(19) United States
(12) Patent Application Publication
(10) Pub. No.: US 2014/0042338 A1
(43) Pub. Date: Feb. 13, 2014

(54) STAGE APPARATUS AND CHARGED PARTICLE BEAM APPARATUS

(71) Applicant: HITACHI HIGH-TECHNOLOGIES CORPORATION, Tokyo (JP)

(72) Inventors: Nobuo Shibata, Kasumigaura (JP); Masahiro Koyama, Tsuchiura (JP); Hironori Ogawa, Hitachinaka (JP); Katsunori Onuki, Hitachi (JP); Hiroyuki Kitsunai, Kasumigaura (JP); Shuichi Nakagawa, Hitachinaka (JP); Masaki Mizuochi, Hitachinaka (JP); Satoru Okabe, Hitachi (JP)

(73) Assignee: Hitachi High-Technologies Corporation, Tokyo (JP)

(21) Appl. No.: 13/789,588

(22) Filed: Mar. 7, 2013

(30) Foreign Application Priority Data
Aug. 10, 2012 (JP) 2012-177688

(51) Int. Cl. H01J 37/20

(52) U.S. Cl. CPC H01J 37/20
USPC 250/453.11

(57) ABSTRACT

A stage apparatus includes a column for irradiating a sample with a charged particle beam, a vacuum sample chamber to which the column is attached, moving tables disposed in the vacuum sample chamber to move the sample relatively to the column, and position detectors for detecting positions of the moving tables. The stage apparatus includes an attachment member disposed between the column and the vacuum sample chamber. The attachment member has an opening which restricts movement of the column in a same direction as directions of the moving tables. Reference mirrors in the position detectors for detecting the positions of the tables are attached to the attachment member. Each of the reference mirrors has an adjustment apparatus to adjust a relative angle between the reference mirror and the laser beam.

### BACKGROUND OF THE INVENTION

The present invention relates to a stage apparatus and a charged particle beam apparatus having the stage apparatus, and in particular to a stage apparatus having a stage position identification device to identify the position of a stage and a charged particle beam apparatus having the stage apparatus.

In the field of semiconductor manufacturing, scanning electron microscopes having a dimension measurement function are used to inspect and evaluate whether shape dimensions of patterns formed on a semiconductor wafer are correct. In the scanning electron microscopes, dimensions are derived by irradiating the top of a wafer with an electron beam, conducting image processing on an obtained secondary electron signal, and discriminating a pattern edge on the basis of a brightness change of a resultant image. With size shrinking of semiconductor devices in recent years, it has become an important subject to obtain a secondary electron image having less noise in, for example, an observation magnification of at least three hundred thousand in order to cope with a design rule of 35 nm node. Furthermore, for improving the contrast by superposing several images one on another, it is necessary to suppress vibration and drift (phenomenon that the stop position shifts with time elapse) of nanometer order in a stage which mounts and retains the wafer.

This apparatus includes a stage for retaining a wafer and moving to a desired position, a measurement unit for measuring the position of the stage, an optical system (column) for irradiating the wafer with an electron beam, and a controller for controlling positioning of the stage and irradiation with an electron beam. For improving the inspection precision, a wafer position measuring technique and an electron beam irradiation control technique which reduce the above-described vibration and drift or which are hardly affected by these phenomena become important.

As for the apparatus which requires high inspection precision, a laser differential dimension measurement scheme has been proposed. In the laser differential dimension measurement scheme, a moving mirror for measuring beam is mounted on a moving stage and a plane mirror for reference beam is disposed in a column or in the vicinity of the column. This scheme aims at reducing the influence of vibration of the column and the influence of drift caused by a temperature change in the column or a table in the vicinity of the place where the column is mounted.

Position detectors for detecting the stage position are disclosed in JP-A-004-153092 and JP-A-2007-67221. An aligner disclosed in JP-A-2004-153092 includes a stage which conducts two-dimensional movement with a photosensitive substrate mounted thereon and a mask stage which conducts two-dimensional movement with a mask having a pattern mounted thereon. And the pattern formed on the mask is transferred to the photosensitive substrate via a projection optical system while the mask stage and the substrate stage are moved successively. A position detector disclosed in JP-A-2004-153092 includes a moving mirror disposed on the stage, and reference mirrors which are disposed on the outside of the projection optical system and which have a direction of thermal expansion in a direction intersecting an axis of measurement conducted by the moving mirror (i.e., in a direction perpendicular to the axis of measurement). The position detector includes an interferometer to irradiate each of the moving mirror and the reference mirrors with an optical beam and detect an interference beam of the optical beams generated by them. Since the reference mirrors are provided so as to have a direction of thermal expansion on a plane perpendicular to an optical axis of the optical system which coincides with a direction intersecting a measurement beam of the measurement mirror, measurement is conducted without a change of a relative position in a measurement direction even if a part (for example, the column) which fixes the reference mirrors moves due to a temperature change.

In JP-A-2007-67221, a manufacturing apparatus such as a projection aligner which transfers a circuit pattern formed on a mask or an electron beam lithography system which forms a circuit pattern on a mask by using an electron beam is disclosed. This manufacturing apparatus includes a column for forming a circuit pattern, a stage for moving with a sample mounted thereon, a moving mirror fixed on the stage, and a reference mirror attached to a reference member which is separate from the column. The manufacturing apparatus further includes an interferometer for receiving a reflected beam from the moving mirror and a reflected beam from the reference mirror and detecting an interference beam, and a column measurement unit for measuring a distance between the reference member and the column. Correction is conducted on stage position information obtained from the interferometer on the basis of information obtained from the column measurement unit.

### SUMMARY OF THE INVENTION

The reference mirrors 19A and 19B included in a position detector which is disclosed in JP-A-153092 are disposed on an outer periphery of a column 4. The column has a flange in its central part, and the column is supported by a center stage part 3B of a column 3 via the flange. The position of the column relative to the laser interferometers can be grasped accurately by attaching the reference mirrors 19A and 19B to the column in this way. However, it is extremely difficult to adjust the attaching angles of the reference mirrors. Especially in the case where the position detector is applied to a charged particle beam apparatus having a vacuum sample chamber, it is difficult to adjust the reflection angles of the reference mirrors in a state in which the column is disposed, because the vacuum sample chamber is a very limited space. In addition, in the case of a high resolution scanning electron microscope, the distance (working distance) between an object lens and a sample is very short and consequently the adjustment of the angle and position of the mirror becomes more difficult.

In JP-A-2007-67221, an example in which a reference member is attached to an inner wall of a top board of a sample chamber and a reference mirror is attached to the reference member is described. In the case where a stage is disposed, however, adjustment is difficult, because the reference member is attached to the inner wall of the sample chamber and the space between the stage and the inner wall is very narrow.

Hereafter, a stage apparatus and a charged particle beam apparatus aiming at implementing reconciliation of higher precision of detection obtained by detecting the stage position with the column taken as reference and facilitation of adjustment of the position detector will be proposed. Furthermore, a stage apparatus and a charged particle beam apparatus aiming at conducting proper stage position detection irrespective of the inclination state of the column will be proposed.

According to one aspect for achieving the object, a stage apparatus or a charged particle beam apparatus includes a column for irradiating a sample with a charged particle beam, a vacuum sample chamber to which the column is attached, moving tables disposed in the vacuum sample chamber to move the sample relatively to the column in at least directions perpendicular to an irradiation direction of the charged particle beam, and position detectors for detecting positions of the moving tables. An attachment member is disposed between the column and the vacuum sample chamber. The attachment member has an opening which restricts movement of the column in a same direction as directions of the moving tables. Each of the position detectors includes a measurement mirror disposed on a corresponding moving table, a laser light source for irradiating the measurement mirror with a laser beam, and a beam splitter disposed between the laser light source and the measurement mirror to split the laser beam, and a reference mirror attached to the attachment member to receive a laser beam obtained as a result of splitting conducted by the beam splitter. The reference mirror has an adjustment apparatus to adjust a relative angle between the reference mirror and the laser beam.

According to another aspect for achieving the object, a stage apparatus or a charged particle beam apparatus includes a column for irradiating a sample with a charged particle beam, a vacuum sample chamber to which the column is attached, moving tables disposed in the vacuum sample chamber to move the sample relatively to the column, and position detectors for detecting positions of the moving tables. Each of the position detectors includes a measurement mirror disposed on a corresponding moving table, a laser light source for irradiating each of the measurement mirror and a reference mirror with a laser beam, and two beam splitters for splitting a laser beam emitted from the laser light source into at least three laser beams. The position detector is disposed so as to irradiate the measurement mirror with a first laser beam among the three laser beams and irradiate different height positions of the reference mirror with a second laser beam and a third laser beam.

According to the above-described configuration, it is possible to implement reconciliation of higher precision of detection obtained by detecting e stage position with the column taken as reference and facilitation of adjustment of the position detector. Furthermore, it becomes possible to conduct proper stage position detection irrespective of the inclination state of the column.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram showing a general configuration of an electron beam microscope apparatus;

FIG. 2 is a diagram showing a method for measuring an X table position with a top board of a sample chamber taken as reference in the general configuration diagram of the electron beam microscope apparatus;

FIG. 3 is an oblique view schematically showing a configuration of a reference mirror and a method of installing the reference mirror;

FIG. 4 is an oblique view schematically showing a method of installing an attachment 50, and reference beam parts 40 and 41 in the sample chamber;

FIG. 5 is an oblique view schematically showing another embodiment of the present invention concerning the configuration of the reference mirror and the method of installing the reference mirror;

FIG. 6 is a diagram schematically showing a notch of the top board which is another embodiment of the present invention;

FIG. 7 is a diagram showing influences of inclination of a column;

FIG. 8 is a diagram showing another embodiment of the present invention for measuring the inclination of the column;

FIG. 9 is a diagram showing changes of coordinate positions of respective regions by taking a case where the column is rotated as an example;

FIG. 10 is a diagram showing another embodiment of the present invention for measuring the stage position by taking the column as reference and measuring the inclination of the column;

FIG. 11 is a diagram showing another embodiment of the present invention for measuring the stage position by taking the column as reference and measuring the inclination of the column only from one side of the sample chamber;

FIG. 12 is a diagram showing a data example for explaining a way of thinking of correction of an SEM image in the present invention;

FIG. 13 is a diagram showing a table position with the column taken as reference and correction data of the SEM image;

FIG. 14 is a diagram schematically showing a wafer pattern of a sample to be inspected;

FIG. 15 is a diagram schematically showing an example in which an image of the wafer pattern is acquired in a SEM apparatus; and

FIG. 16 is a diagram schematically showing an example in which an SEM image is corrected.

### DESCRIPTION OF THE EMBODIMENTS

In charged particle beam apparatuses represented by the electron microscope, the distance (work distance) between a bottom face of a column and a wafer surface which is an object to be inspected is short. Furthermore, in the case where position detection of a stage is conducted by using the laser differential dimension measurement scheme, it is necessary to dispose a plane mirror for reference beam in a position which is extremely close to a charged particle optical system (column). For implementing high precision dimension measurement, adjustment of the plane mirror is indispensable. In an apparatus having a short work distance, however, the adjustment is difficult. Furthermore, a space for mounting the plane mirror must be secured. For securing the space, the top board of the sample chamber is made high and a column is supported in a high position. This brings about not only a large sized sample chamber and a higher cost, but also a largely deviated electron beam irradiation position because the column is supported in a high position and the column is inclined.

In view of the above-described problem, in an embodiment described hereafter, a laser differential dimension measurement scheme in which a plane mirror is formed near a column for a reference beam, a stage positioning control apparatus which makes possible high precision stage position measurement and correction of a shaking image without being affected by inclination of the column, and a stage apparatus and a charged particle beam apparatus having the stage positioning control apparatus will be described.

The stage positioning control apparatus proposed in the present embodiment includes, for example, a column for irradiating a sample with an electron beam, a base having a guide mechanism in a vacuum sample chamber mounting the column, a table for moving along the guide mechanism with the sample mounted thereon, a drive mechanism for driving the table, and a position detector for measuring the position of the table. And in the stage positioning control apparatus, an annular attachment (attachment member) disposed on a top board of the sample chamber and a reference mirror member having a reference mirror on a bottom part of the attachment are formed, and a measurement mirror is disposed on the stage. And stage positioning control is exercised on the basis of stage position information which is obtained from interference between a reference beam obtained by irradiating the reference mirror with a laser beam and a measurement beam obtained by irradiating the measurement mirror with a laser beam. Measurement of the stage position with the column taken as reference is possible. Even if there are drift caused by a temperature change of the column and vibration in the horizontal direction, therefore, it becomes possible to conduct high precision stage position measurement with little influence of them. In addition, an opening for inserting the column is provided through the attachment to make it possible to insert the column into the attachment substantially closely. Owing to this opening, it is possible to restrict the movement of the column in an X-Y direction. In addition, since the attachment directly follows the vibration of the column, it becomes possible to conduct high precision position measurement. Furthermore, an opening which allows insertion of the attachment and which restricts the movement of the attachment in the X-Y direction is provided through the top board of the vacuum sample chamber. The attachment is provided with a flange to restrict downward movement from the opening. It is also possible to take out the reference mirror and adjust it, by forming the attachment so as to be attachable to and detachable from the top board. In addition, it can be easily implemented to adjust the reference mirror even in a state in which the reference mirror is attached to the vacuum sample chamber, by providing an adjustment knob for adjustment opposite the opening of the attachment.

In high resolution electron microscopes having a short working distance, the space in which the reference mirror can be disposed is very limited. Therefore, it can be said that the above-described configuration is a technique which is very effective for the purpose of adjusting the reference mirror with high precision.

As for the reference mirror having the adjustment function, it is desirable that the reference beam member includes a plane mirror fixed to a holder, a plurality of compression springs disposed between the holder and a support plate, and a plurality of bolts which engage with the holder from the outside of the support holder to press the compression springs, and the angle of the plane mirror with respect to the reference beam can be adjusted freely by operating the plurality of volts after the reference beam member is attached to the attachment. Owing to such a configuration of the reference mirror, it becomes possible to adjust the angle and position of the plane mirror in the limited space with high precision.

Furthermore, it is desirable to provide a notch in the top board of the vacuum sample chamber to take in a passage trajectory of the reference beam and the reference beam member and conduct stage positioning on the basis of the stage position information which is obtained from interference between a reference beam obtained by irradiating the reference mirror with a laser beam and a measurement beam obtained by irradiating the measurement mirror with a laser beam. As a result, the height of the sample chamber is lowered, resulting in reduction of the size and cost. Furthermore, the distance between the attachment position of the column disposed over the top board of the sample chamber and the wafer surface which is the sample to be inspected can be made small by lowering the height of the sample chamber. As a result, it becomes possible to cause a deviation of the irradiation position of the electron beam due to inclination of the column to become small.

In another example described in the present embodiment, a second reference beam member is separately disposed on the bottom of the attachment in a position opposite the disposed position of the first reference beam member described above with an angle of 180 degrees (around the beam trajectory of the column). An upper part of a reference mirror in the second reference beam member is irradiated with a reference beam, whereas a lower part of the reference mirror is irradiated with a measurement beam. An interferometer is disposed to measure the inclination of the column on the basis of a differential distance between the reference beam and the measurement beam. Owing to this configuration, it becomes possible to execute the stage position measurement with the column taken as reference and inclination measurement of the column simultaneously. Since the stage position with the column taken as reference and the inclination of the column can be measured independently, it becomes possible to grasp a vibration phenomenon at the time of stage positioning control separately.

In another example in the embodiment described hereafter, an incident laser beam is split into three laser beams by a plurality of beam splitters and benders. An upper part of a reference mirror in a reference beam member is irradiated with a first laser beam included in the three laser beams. A lower part of the reference mirror in the reference beam member is irradiated with a second laser beam included in the three laser beams. And a measurement (moving) mirror mounted on the stage is irradiated with a third laser beam included in the three laser beams. Stage position information with the column position taken as reference is obtained on the basis of interference between a first reflected beam which is obtained by splitting a reflected beam obtained by irradiating the lower part of the reference mirror in the reference beam member with the second laser beam into two reflected beams and a reflected beam which is obtained by irradiating the measurement mirror on the stage with the third laser beam. In addition, inclination of the column is measured on the basis interference between a reflected beam which is obtained by irradiating the upper part of the reference mirror in the reference beam member with the first laser beam and a second reflected beam which is obtained by splitting the reflected beam obtained by irradiating the lower part of the reference mirror in the reference beam member with the second laser beam into the two reflected beams. Owing to this configuration, it becomes possible to execute the stage position measurement with the column taken as reference and inclination measurement of the column by using an optical system provided only on a side face of one side of the sample chamber.

According to the configurations described in the present embodiment hereafter, measurement of the stage position at a high level which is demanded for a sample stage in the electron microscope apparatus used, for example, in the semiconductor manufacturing field can be made possible.

Hereafter, a stage positioning control apparatus, and a stage apparatus and a charged particle beam apparatus having the stage positioning control apparatus will be described with reference to FIGS. 1 to 14. First, a general configuration of an electron beam microscope apparatus which is one kind of the charged particle beam apparatus and an outline of a wafer pattern evaluation method will now be described. FIG. 1 is a diagram showing a general configuration of an electron beam microscope apparatus. In FIG. 1, an electron beam microscope apparatus having a sample stage mounted thereon is shown as an example. In FIG. 1, a sample stage 3 is mounted within a sample chamber 2 which can be subjected to vacuum evacuation by a vacuum pump 1. The sample stage 3 includes a base 4, an X table 5, and a Y table 6. The X table 5 is restrained by an X slide guide member 7 (and a member 8 which is not illustrated) disposed on the base 4 to function as a guide mechanism, and the X table 5 can move in one direction (a direction indicated by an arrow in FIG. 1 which is referred to as X direction). The X table 5 is pushed or pulled by an X rod 10 which conducts rectilinear movement in response to rotation of an X ball screw 9 functioning as a drive mechanism.

A tip of the X rod 10 is coupled to the X table 5 by a part which is not illustrated. The X ball screw 9 is coupled to a shaft 11 subjected to vacuum seal, and consequently the X ball screw 9 can be rotated by a motor 12. Furthermore, a Y slide guide member 13 intersecting the X slide guide member 7 (and 8) at right angles is formed on the X table 5 in the same way. The Y table 6 moves in one direction (a direction coupling the rear side and this side in FIG. 1 which is referred to as Y direction) along the Y slide guide member 13. The Y table 6 is coupled to a Y rod (not illustrated). On the other hand, a sample holder 15 is mounted on the Y table 6, and a wafer 16 is fixed on the sample holder 15.

Furthermore, a bar mirror 17 is attached to the top of the Y table 6 for the purpose of stage position control. Reference numeral 18 denotes a laser interference dimension measurement controller. The bar mirror 17 is irradiated with a laser beam emitted from the laser interference dimension measurement controller 13 via an interferometer 19. A reflected beam from the bar mirror 17 is incident upon the interferometer 19. In the interferometer 19, the laser beam emitted from the laser interference dimension measurement controller 18 earlier is split by a polarizer beam splitter (not illustrated) and a laser beam (reference beam) is generated. A laser beam obtained by reflecting the reference beam from a reference mirror (not illustrated) and the laser beam reflected from the bar mirror 17 are superposed to cause interference. A resultant beat signal beam is received by a receiver (not illustrated). The received beat signal beam is transferred to the laser interference dimension measurement controller 18, and converted to a position of the bar mirror 17 with a position of the reference mirror within the laser interference dimension measurement controller 18 taken as reference, i.e., position information of the X table 5.

A controller 20 exercises stage position control in the X direction by controlling the motor 12 on the basis of a position of the sample stage 3 measured by the laser interference dimension measurement controller 18. In FIG. 1, only the bar mirror 17 for X direction stage position control, the laser interference dimension measurement controller 18 for X direction, and the motor 12 for X direction drive are shown. However, a bar mirror, a laser interference dimension measurement controller, and a motor are provided for the Y direction as well in the same way to exercise stage position control in the Y direction. The controller 20 functions as “positioning controller” in cooperation with the laser interference dimension measurement controller 18. Specifically, the controller 20 is an apparatus including a main controller for reading out a program recorded in an internal memory and executing desired procedures successively and a motor drive controller.

On the other hand, a column 27 is mounted on an upper part of the sample chamber 2. The column 27 incorporates an electron source 21 functioning as an electron beam source, an electron lens 23 for changing a trajectory of an electron beam 22, an objective lens 24 for focusing the electron beam 22, and an electron detector 26 for taking in secondary electrons 25 emitted from the wafer 16. A signal from the electron detector 26 is subject to signal processing in a controller 28, and a resultant signal is sent to a monitor 29 for observation. The electron beam 22 is applied from a direction (Z direction) which is perpendicular to the movement direction (X-Y direction) of the stage.

Operation of the electron beam microscope apparatus will now be described. Usually, as a pattern shape evaluation method of a wafer, a position of a desired pattern in a chip and a chip selected to be subject to pattern evaluation out of chips arranged on one wafer are registered previously by using coordinates. At the time of evaluation, the controller 20 automatically moves the sample stage to the coordinate position on the basis of registered contents, then irradiates the top of the wafer 16 with the electron beam 22, conducts scanning by using the electron lens 23, acquires a secondary electron image in the range of several tens thousands to several hundreds thousands, and displays the secondary electron image on the monitor 29. And the controller discriminates a pattern shape on the basis of a change of brightness of the secondary electron image, and calculates dimension values of a specified shape (such as a pattern line width and a pitch). Then, the sample stage is moved to a coordinate position of the next registered chip, and image acquisition is repeated in the same way. In this way, pattern shape evaluation of the wafer is conducted.

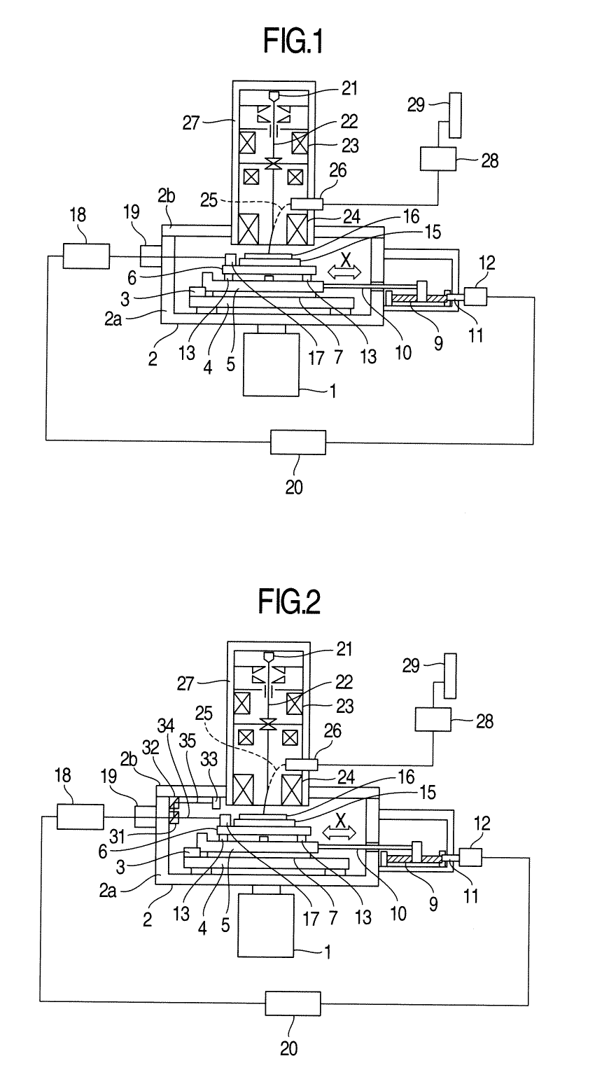

In FIG. 1, the X table position of the stage is measured by taking the reference mirror disposed in the interferometer 19 as reference. On the other hand, FIG. 2 shows a method for measuring the X table position by taking the top board of the sample chamber in the vicinity of the column 27 as reference. In FIG. 2, the same components as those shown in FIG. 1 are denoted by like reference numerals. Reference numeral 33 denotes a plane mirror. A laser beam emitted from the laser interference dimension measurement controller 18 is split into two beams by a beam splitter 31. The bar mirror 17 is irradiated with one of the two beams. The plane mirror (reference mirror) 33 is irradiated with the other beam bent by a beam bender 32. A measurement beam 34 and a reference beam 35 reflected respectively from the bar mirror 17 and the plane mirror (reference mirror) 33 are superposed one on another and received by a receiver (not illustrated) in the same way as the foregoing description. A received beat signal beam is transferred to the laser interference dimension measurement controller 18 and converted to a position of the bar mirror 17 with a position of the reference mirror 33 taken as reference, i.e., position information of the X table 5.

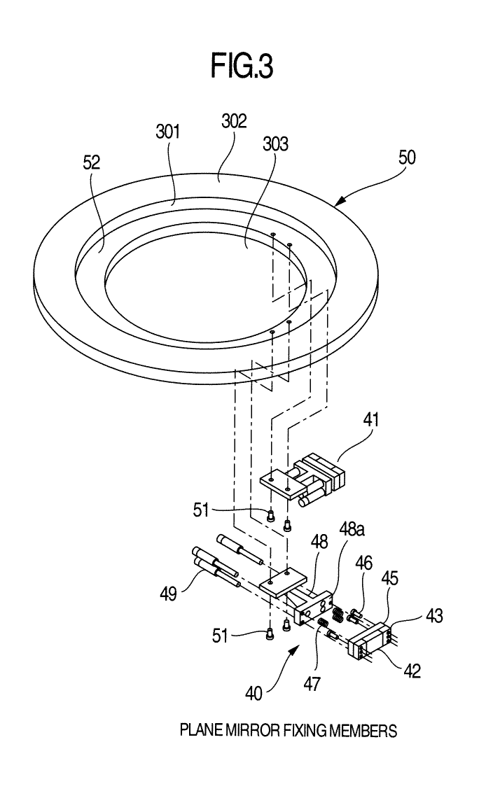

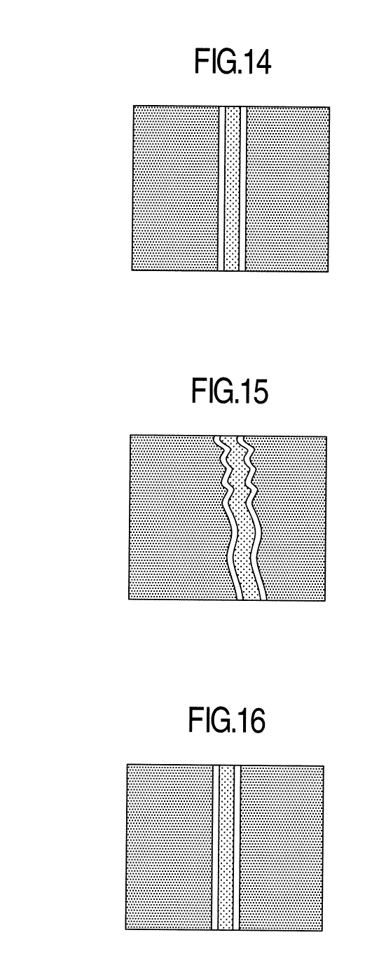

A positioning control method of the sample stage in the electron beam microscope apparatus will now be described in detail with reference to FIG. 3 and FIG. 14. FIG. 3 is an oblique view schematically showing a configuration of the reference mirror and a method of installing the reference mirror. Reference numerals 40 and 41 denote plane mirror parts disposed in directions which are perpendicular to each other to measure the stage position in the X direction and Y direction. The plane mirror parts 40 and 41 have the same configuration. However, reference numeral 40 represents a configuration obtained by disassembling the reference mirror part, whereas 41 represents an exterior view of the assembled reference mirror part. The plane mirror part 40 (and 41) includes a plane mirror 42, a plane mirror holder 43, a support plate 45, bolts 46, compression springs 47, a fixing part 48, and adjustment bolts 49. The plane mirror 42 is fixed to the plane mirror holder 43 by means of adhesion or the like. The plane mirror holder 43 is fixed to the support plate 45 by tightening the bolts 46.

Counter bores are provided in screw parts of the support plate 45 engaged with the bolts 46 to prevent heads of the bolts 46 from projecting from the surface. A plurality of concave receiving holes are provided on a front face 48a of a fixing part 48. The compression springs are inserted partially into the receiving holes, and the adjustment volts 49 are engaged with screw parts provided on the support plate 45 through holes of the fixing part 48. As a result, the fixing part 48 and the plane mirror holder 43 are assembled into one body. It becomes possible to freely change the direction of the plane mirror 42 disposed in the front by conducting tightening or loosening operation on the plurality of adjustment bolts. In FIG. 3, reference numeral 50 denotes an attachment. The attachment 50 has a flange part 52 with a step inside thereof. The plane mirror parts 40 and 41 are fixed under the attachment 50 by using bolts 51.

Furthermore, an annular part 0 having an outer circumference which fits into an opening for column provided in the vacuum sample chamber closely is provided in the attachment 50. The annular part 301 is provided to connect the flange 52 to another flange 302 which is supported to the top board of the vacuum sample chamber. Furthermore, an inner wall of the annular part 301 has an inner circumference face into which the column of the electron beam microscope apparatus fits closely. Relative movement between the column and the attachment 50 in the X-Y direction and in the inclination direction is prevented. The column of the electron beam microscope apparatus is housed in the opening 303 in the annular part 301 as described above. And the column fits in the opening 303 closely to prevent relative movement between the attachment 50 and the column.

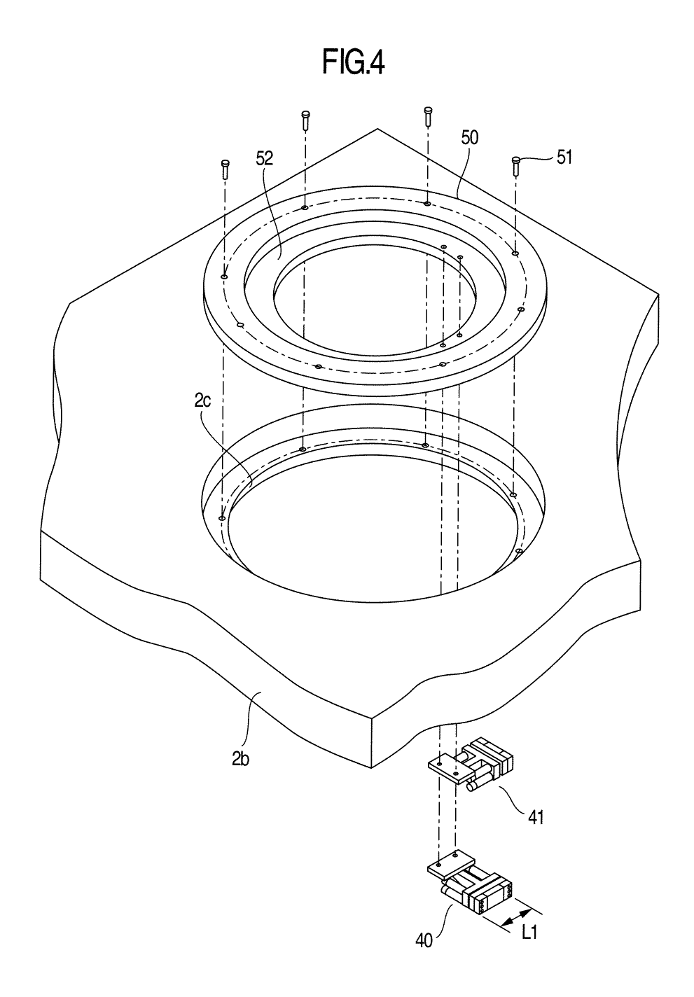

FIG. 4 is an oblique view schematically showing a method of installing the attachment 50, and the reference beam parts 40 and 41 in the sample chamber. As illustrated, the attachment 50 is installed in a flange part 2c provided in a top board 2b of the sample chamber and fixed by using bolts 51. As described above, the flange 52 is provided inside the attachment 50. A column (not illustrated) is mounted on the flange part.

The column 27 includes heavy components such as the electron source 21, the electron lens 23 and the objective lens 24 for focusing the electron beam. According to the present invention, the column is mounted on the top board via the attachment. In other words, owing to a divided structure in which the column and the attachment are formed as separate parts, it becomes possible to adopt an attachment having a material and shape of high rigidity.

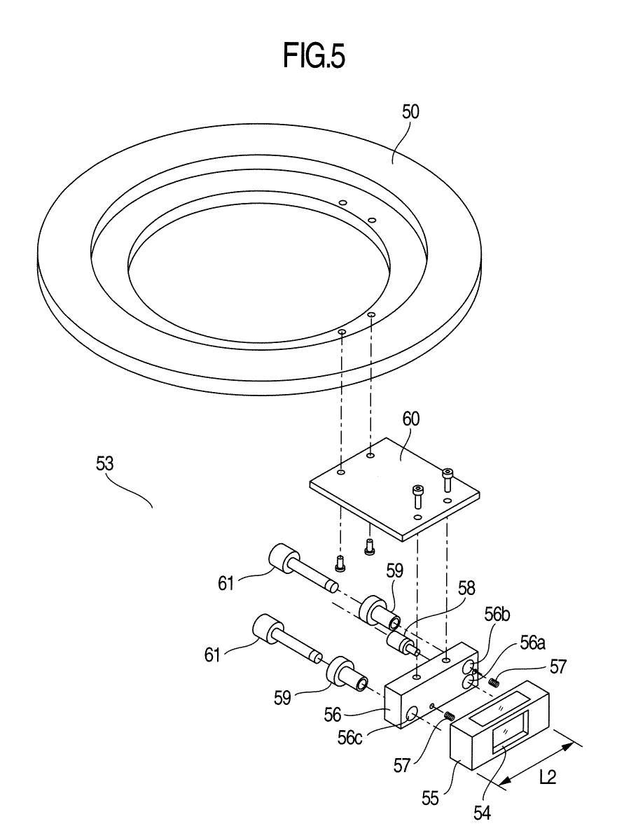

FIG. 5 is an oblique view schematically showing another embodiment concerning the configuration of the reference mirror and the method of installing the reference mirror. In FIG. 5, a configuration obtained by disassembling a reference mirror part 53 is shown. The reference mirror part 53 includes a plane mirror 54, a plane mirror holder 55, a base 56, extension springs 57, a fixing bolt 58, screw guides 59, a fixing plate 60, and adjustment bolts 61. In FIG. 5, first, in a state in which extension force is generated in the extension springs 57, both ends of the extension springs 57 are attached to the base 56 and the plane mirror holder 55, respectively. Then, the fixing bolt 58 is engaged with a screw hole 56a of the base 56, and a tip of the fixing bolt 58 is pressed against the plane mirror holder 55. The screw guides have screws inside and outside. The screw guides 59 are engaged with screw holes 56b and 56c of the base 56, and fixed to the base 56 by lock mechanisms which are not illustrated. As a result, the screw guides 59 and the base 56 are united into one body. Then, the adjustment bolts 61 are engaged with the inside screws of the screw guides 59. Tips of the adjustment bolts 61 are pressed against a side face of the plane mirror holder 55, and positions of pressing are adjusted forward and backward. As a result, it becomes possible to freely change the direction of the plane mirror 54 disposed in the front in a state in which the tip of the fixing bolt 58 becomes a fulcrum and extension force is always applied by the extension springs 57. The base 56 is fixed to the fixing plate 60, and then the fixing plate 60 is mounted on the attachment 50. As a result, a reference mirror configuration similar to that in FIG. 3 is obtained. As for the two axes of the XY stage, the reference mirror configurations should be mounted in directions which are perpendicular to each other in the same way.

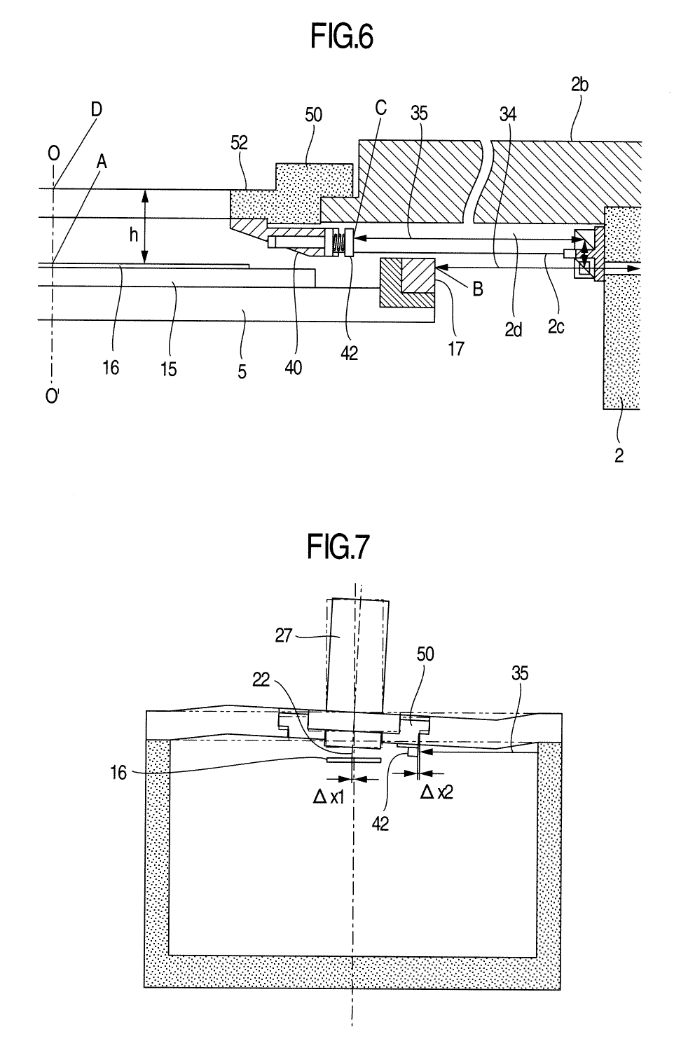

FIG. 6 is a diagram schematically showing another embodiment of the present invention. FIG. 6 shows a section of only the right side of a central part (O-O′ line) of the sample chamber 2 and an upper part thereof. The same parts as those in the foregoing description are denoted by like reference characters. In FIG. 6, reference numeral 34 denotes a measurement laser beam with which the bar mirror 17 is irradiated, and reference numeral 35 denotes a reference laser beam with which the plane mirror 42 disposed at a tip of the plane mirror part 40. In FIG. 6, reference character 2c denotes a rear face of the top board 2b, and reference character 2d denotes a notch obtained by hollowing out the back of the top board 2b to prevent the laser beam from being intercepted. The size of the notch 2d in a direction perpendicular to the paper is made slightly larger than the width L1 (or L2) of the plane mirror part 40 shown in FIG. 4 (or the plane mirror part 54 shown in FIG. 5). The measurement of the stage position with the column taken as reference becomes possible without making the top board thin, i.e., without lowering the rigidity of the top board, by providing the notch for laser beam in the top board in this way.

Furthermore, the position of the attachment 50 is lowered to the inside of the sample chamber 2 by forming the notch. As a result, the position of the flange face 52 to which the column is attached can also be made nearer the height of the wafer 16. As a distance h between the column attaching position 52 and the wafer surface becomes smaller, the irradiation position deviation of the electron beam 22 caused by inclination of the column becomes small. Influence of the inclination of the column can be corrected as described later. However, nothing is so good as small inclination.

FIG. 7 is a diagram showing influences of inclination of the column with emphasis. If the column 27 inclines, the position where the wafer 16 is irradiated with the electron beam 22 deviates with a deviation value of Δx1). In addition, the attachment 50 which is one with the column 27 also inclines at the same time. Then, the plane mirror 42 also inclines. The position of the reference beam 35 is immobile. However, a point at which the plane mirror 42 is irradiated with the reference beam 35 is deviated by the inclination of the plane mirror 42. As a result, an error is caused in the laser measurement value (with a deviation value of Δx2).

The above-described method of measuring the stage position with the column taken as reference can reduce the influence of the drift of the column 27 in the horizontal direction caused by a temperature change and the influence of vibration. In some cases, however, the influence of the inclination of the column shown in FIG. 7 remains.

FIG. 8 is a diagram showing a method for measuring the inclination of the column 27. In other words, laser measurement of the column inclination (vibration) using a differential method is conducted on an opposite side of column reference measurement with an angle of 180 degrees. FIG. 8 shows a section of only the left side of a central part (O-O′ line) of the sample chamber 2 shown in FIG. 6, i.e., the sample chamber on a side opposite to the part of the sample chamber shown in FIG. 6 with 180 degrees and an upper part thereof. As compared with the direction of the plane mirror 42 in FIG. 6, the plane mirror 42 faces to the opposite side in FIG. 8. Reference numerals 34 and 35 respectively denote a measurement laser beam and a reference laser beam with which the plane mirror 42 is irradiated. It becomes possible to measure the inclination of the plane mirror 42 by causing differential interference between the measurement laser beam 34 and the reference laser beam 35. Since the plane mirror 42, the attachment 50 and the column 27 are united as one body, it becomes possible to measure the inclination of the column 27 by measuring the inclination of the plane mirror 42. The deviation Δx1 of the position where the wafer 16 is irradiated with the electron beam 22 when the column 27 inclines and the error Δx2 of the laser measurement value caused by the inclination of the plane mirror 42 will now be described.

In FIG. 6, points A, B, C and D are shown. The points A, B, C and D are points before the column inclines. The point A is a position where the wafer 16 is irradiated with the electron beam 22. The point B is a position where the bar mirror 17 is irradiated with the measurement beam 34. The point C is a position where the plane mirror 42 is irradiated with the reference beam 35. The point D indicates a center position of the flange 52 of the attachment 50.

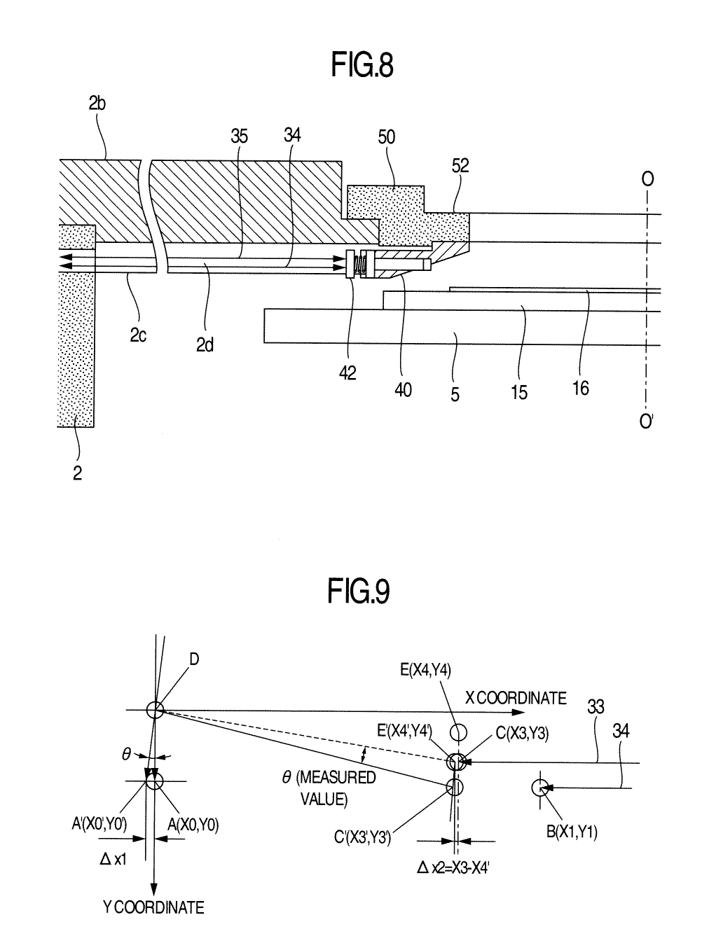

FIG. 9 shows changes of coordinate positions of respective points by taking a case where the column rotates around the center D of the flange 52 as an example. Two-dimensional XY coordinates with the point D taken as origin are shown in FIG. 9. The points A, B and C are respectively moved to points A′, B′ and C′ by rotation of the column (with a rotation angle of θ). A point E′ is a point where the mirror surface is irradiated with the reference laser beam after the rotation. A point E represents the point E′ before the rotation. Coordinates of the points C′ (X3′, Y3′) and E′ (X4′, Y4′) after the rotation are obtained as follows by using linear conversion formula of the rotational movement.

X3′=X3·cos θ−Y3·sin θ (1)

Y3′=X3·sin θ+Y3·cos θ (2)

X4′=X4·cos θ−Y4·sin θ (3)

Y4′=X4·sin θ+Y4·cos θ 4)

Supposing that the reference laser beam is not changed in the Y axis direction by the rotation of the column, it follows that

Y4′=Y3 (5)

Since the angle of the reference mirror is adjusted to be perpendicular to the reference beam, it follows that

X3=X4 (6)

The deviation Δx2 of the laser measurement with the barrel taken as reference caused by the rotation is represented by the following equation.

Δx2=X3−X4′ (7)

X4′ is represented as a function of X3 and Y3 by using Equations (1) to (6).

X4′=X3·cos θ−2Y3·sin θ+X3·(sin θ)²+Y3·cos θ sin θ( (8)

Since X3 and Y3 are already known beforehand, it becomes possible to find Δx2 from Equation (6) and Equation (7) if the rotation angle of the column can be measured.

Furthermore, the deviation Δx1 of the irradiation position of the electron beam caused by the rotation is found by the following Equation.

Δx1=Y0·tan θ (9)

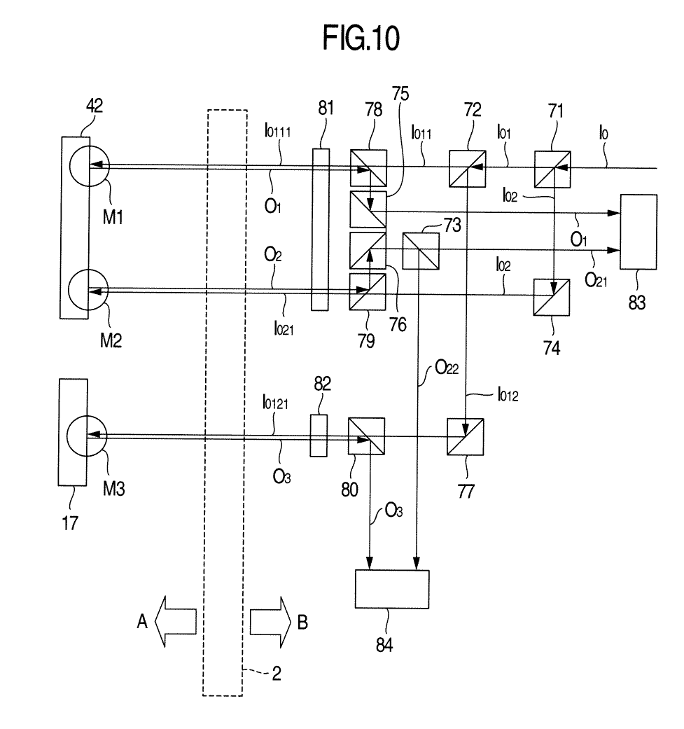

FIG. 10 is a diagram showing another embodiment for measuring the stage position by taking the column as reference and measuring the inclination of the column. The rotation angle θ is measured. From coordinates of C obtained by using the linear conversion formula of the rotational movement and the measured value of θ, Δx1 and Δx2 are calculated.

Δx×1: irradiation position of electron beam caused by rotation

Δx2 change of measured value of column reference caused by rotation (even if the tables do not move)

In FIG. 8, a different plane mirror part 40 is formed on a side opposite with 180 degrees to the stage position measurement unit with the column taken as reference, and the inclination of the column 27 is measured by using the different plane mirror part 40. On the other hand, FIG. 10 shows an optical system which measures the stage position with the column taken as reference and measures the inclination of the column 27 only from one side of the side face of the sample chamber. In FIG. 10, reference numerals 71, 72 and 73 denote beam splitters, 74, 75, 76 and 77 beam benders, and 78, 79 and 80 polarizer beam splitters. Furthermore, reference numerals 81 and 82 denote quarter-wave plates, 42 a plane mirror mounted on a plane mirror part, and 17 a bar mirror provided on the X table. An arrow A side of the sample chamber 2 is vacuum, whereas an arrow B side is the atmosphere. Laser beams described later passes the atmosphere and the vacuum via a viewer port (not illustrated) provided in a vacuum chamber.

Laser beam paths will now be described. A laser beam I₀ which is incident from external incident upon the beam splitter 71, and split to a transmitted beam I₀₁ and a reflected beam I₀₂. The transmitted beam I₀₁ is incident upon the polarizer beam splitter 78. At this time, a beam I₀₁₁₁ of a P polarization component is transmitted, and the plane mirror 42 is irradiated with the beam I₀₁₁₁ via the quarter-wave plate 81. A reflected beam O₁ from the plane mirror 42 is incident upon the polarizer beam splitter 78 via the quarter-wave plate 81. Since the reflected beam O₁ is provided with a phase difference by the quarter-wave plate 81 and the polarization component is changed, the reflected beam O₁ is reflected by the polarizer beam splitter 78, then incident upon the beam bender 75, and then incident upon a detector 83 (beam O₁).

The beam I₀₂ reflected by the beam splitter 71 is refracted by the beam bender 74 and then incident upon the polarizer beam splitter 79. At this time, a beam I₀₂₁ of a P polarization component is transmitted, and the plane mirror 42 is irradiated with the beam I₀₂₁ of via the quarter-wave plate 81.

A reflected beam O₂ from the plane mirror 42 is incident upon the polarizer beam splitter 79 via the quarter-wave plate 81. Since the reflected beam O₂ is provided with a phase difference by the quarter-wave plate 81 and the polarization component is changed, the reflected beam O₂ is reflected by the polarizer beam splitter 79, then incident upon the beam bender 76, then incident upon the beam splitter 73, and split into a beam O₂₁ and a beam O₂₂. The beam O₂₁ is incident upon the detector 83, whereas the beam O₂₂ is incident upon a detector 84 (beam O₂).

A beam I₀₁₂ reflected by the beam splitter is refracted by the beam bender 77, then incident upon the polarizer beam splitter 80. At this time, a beam I₀₁₂₁ of a P polarization component is transmitted, and the bar mirror 17 disposed on the X table 5 is irradiated with the beam I₀₁₂₁ via the quarter-wave plate 82.

A reflected beam O₃ from the bar mirror 17 disposed on the X table 5 is incident upon the polarizer beam splitter 80 via the quarter-wave plate 82. Since the reflected beam O₃ is provided with a phase difference by the quarter-wave plate 82 and the polarization component is changed, the reflected beam O₃ is reflected by the polarizer beam splitter 80, then incident upon the detector 84 (beam O₃).

Each of the detectors 83 and 84 acquires an interference signal obtained by superposing two incident beams, and measures a differential distance between beams. As a result, it becomes possible to measure the X stage position with the column taken as reference on the basis of differential measurement between an M2 part of the plane mirror 42 and an M3 part of the bar mirror 17 provided on the X table 5. Furthermore, it becomes possible to measure the inclination of the column on the basis of differential measurement between an M1 part (located higher than the M2 part) of the plane mirror 42 and the M2 part of the plane mirror 42.

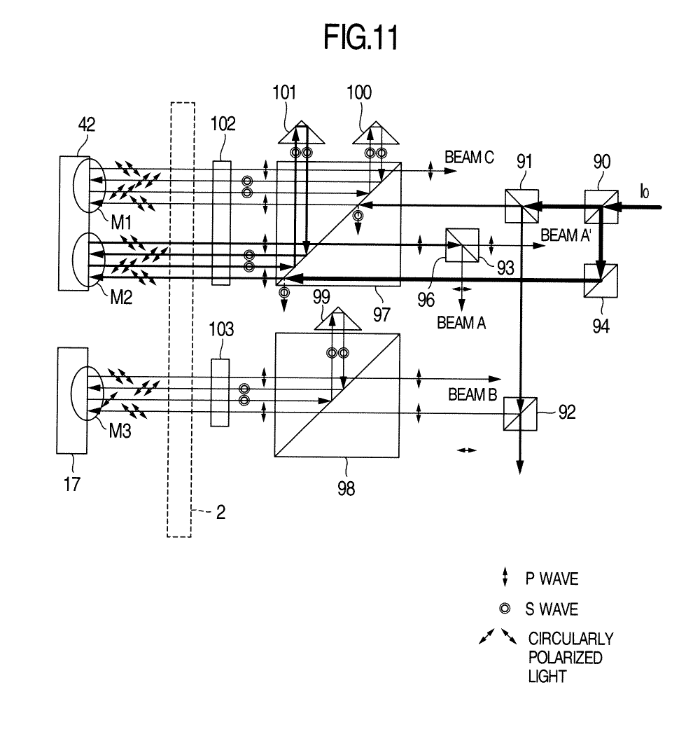

FIG. 11 is a diagram showing another embodiment of the present invention for measuring the stage position by taking the column as reference and measuring the inclination of the column 27 from one side of the sample chamber. In FIG. 11, reference numerals 90, 91, 92 and 93 denote beam splitters, 94 a beam bender, 96, 97 and 98 polarizer beam splitters, 99, 100 and 101 corner cube mirrors, and 102 and 103 quarter-wave plates. In the configuration shown in FIG. 10, beams reflected by the plane mirror 42 and the bar mirror 17 only once are used. On the other hand, in the case of FIG. 11, beams are reflected twice. In FIG. 11, an incident beam at the second time is shown with a deviation in the height direction at each of the reflection parts M1, M2 and M3. However, beam paths in principle are shown for convenience. As a matter of fact, the optical system is configured to cause incident beams at the first time and the second time to have the same horizontal height. In FIG. 11, a longitudinal arrow indicates a P wave of a laser beam, a double circle indicates an S wave, and an oblique arrow indicates circularly polarized light. Oblique arrows at different angles indicate circularly polarized light which are different from each other in rotation direction. In the present embodiment, a beam A, a beam A′, a beam B, and a beam C are obtained finally as reflected beams. The beams A and B, and the beams A′ and C are incident upon the detectors 84 and 83 via mirrors which are not illustrated, respectively. In the same way as the case of FIG. 10, it becomes possible to conduct measurement of the X stage position with the column taken as reference on the basis of differential measurement between the M2 part of the plane mirror 42 and the M3 part of the bar mirror 17 provided on the X table 5. Furthermore, it becomes possible to measure the inclination of the column on the basis of differential measurement between the M1 part of the plane mirror 42 and the M2 part of the plane mirror 42.

FIG. 12 shows a data example for explaining a way of thinking of correction of an SEM image. FIG. 12 shows a case where the column and the stage are vibrating and a drift (a phenomenon that a horizontal movement is caused with time) is occurring in the column and the stage as an example. Each waveform in FIG. 12 differs from the actual waveform. For example, the vibration of the stage is caused by superposition of vibrations of several frequency components, and a complicated vibration behavior appears with time. Supposing that the shaking of the column as shown in FIG. 7 is a sine wave having an amplitude a1 and a frequency F1, the shaking of the column is represented by a waveform A shown in FIG. 12 (the beam position which changes with time is represented by ΔX1). The deviation (ΔX2=X3−X4′) of the reference beam position caused by the shaking of the column at this time and represented by Equation (7) is indicated by a waveform B (the deviation which changes with time is represented by ΔX2) Its amplitude is supposed to be a2. It is supposed that the reference mirror shakes with the column as one body and the drive frequency of the deviation of the reference beam position is the same frequency F1 as that of the shaking of the column. On the other hand, disturbance such as the floor vibration, vibration of the vacuum pump, and sound pressure variation generated by a fan in the room is propagated via the vacuum chamber, and consequently the stage vibrates. Supposing that the vibration waveform of the stage is a sine wave having an amplitude a3 and a frequency F2, the vibration waveform of the stage is represented by a waveform C in FIG. 12 (the stage vibration which changes with time is represented by ΔX3). The relation F1<F2 is supposed on the basis of past experience of measurement of the stage vibration and the column vibration. Supposing that the relative value of drift of the reference mirror and the stage is linear with respect to the time axis, it is represented by a waveform D (the beam position which changes with time is represented by ΔX4).

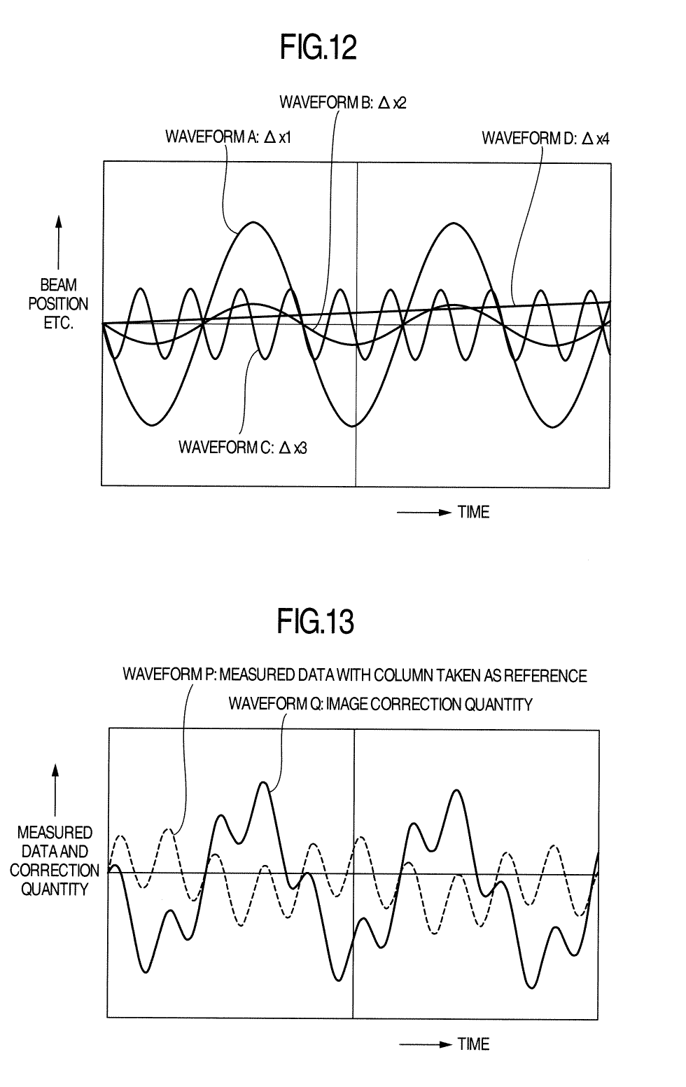

The beam position deviation ΔX1 and the reference beam position deviation ΔX2 are found on the basis of a measurement result of the inclination θ of the column by using Equation (7), Equation (8) and Equation (9). The stage vibration ΔX3 and the drift ΔX4 are found by subtracting the reference beam position deviation ΔX2 from the stage position measurement result with the column taken as reference. A result obtained by finding the table position with the column taken as reference by using the waveforms shown in FIG. 12 is represented by a waveform P indicated by a dashed line in FIG. 13. In addition, the beam position on the wafer surface obtained from the waveform P and the beam position waveform A shown in FIG. 12 is represented by a waveform Q of a solid line. In other words, when an SEM image is acquired under the conditions shown in FIG. 12, an image is taken in with the irradiation position of the electron source being deviated with time as represented by the waveform Q (image correction data) in FIG. 13. Correction of the SEM image based on the obtained SEM image and image correction data is made possible by synchronizing SEM image acquisition timing with the stage position measurement with the column taken as reference and the column inclination measurement.

FIG. 14 schematically shows a wafer pattern of a sample to be inspected. FIG. 15 schematically shows an example in which an image of the wafer pattern shown in FIG. 14 is acquired by a SEM apparatus. The acquired image represents an example in which image shaking is caused by the drift, vibration and inclination of the column and the vibration of the stage. If there is image correction data at the time of image acquisition shown in FIG. 14 (which has no relation to FIG. 15), however, off-line correction can be conducted by using the image correction data and an image shown in FIG. 16 which is close to the original wafer pattern can be obtained.

It should be further understood by those skilled in the art that although the foregoing description has been made on embodiments of the invention, the invention is not limited thereto and various changes and modifications may be made without departing from the spirit of the invention and the scope of the appended claims.

1. A stage apparatus including a column for irradiating a sample with a charged particle beam, a vacuum sample chamber to which the column is attached, moving tables disposed in the vacuum sample chamber to move the sample relatively to the column in at least directions perpendicular to an irradiation direction of the charged particle beam, and position detectors for detecting positions of the moving tables,
the stage apparatus comprising an attachment member disposed between the column and the vacuum sample chamber, the attachment member having an opening which restricts movement of the column in a same direction as directions of the moving tables,
each of the position detectors comprising:
a measurement mirror disposed on a corresponding moving table;
a laser light source for irradiating the measurement mirror with a laser beam;
a beam splitter disposed between the laser light source and the measurement mirror to split the laser beam; and
a reference mirror attached to the attachment member to receive a laser beam obtained as a result of splitting conducted by the beam splitter.

2. The state apparatus according to claim 1, wherein an adjustment apparatus is provided to adjust a relative angle between the reference mirror and the laser beam.

3. The stage apparatus according to claim 2, wherein the adjustment apparatus comprises:
fixing members for fixing the reference mirror to the attachment member;
spring members disposed between the fixing members and the reference mirror; and
a plurality of adjustment bolts for adjusting an attitude of the reference mirror.

4. The state apparatus according to claim 1, wherein a notch is provided in a top board of the vacuum sample chamber to house an irradiation trajectory of the laser beam and the reference mirror.

5. The state apparatus according to claim 1, wherein the attachment member is annular.

6. The state apparatus according to claim 5, wherein
a first reference mirror is attached to the annular attachment member, and
a second reference mirror is attached to the annular attachment member on an opposite side of a center of the attachment member from the first reference mirror.

7. A charged particle beam apparatus comprising the stage apparatus according to claim 1.

8. A stage apparatus including a column for irradiating a sample with a charged particle beam, a vacuum sample chamber to which the column is attached, moving tables disposed in the vacuum sample chamber to move the sample relatively to the column, and position detectors for detecting positions of the moving tables,
each of the position detectors comprising:
a measurement mirror disposed on a corresponding moving table;
a laser light source for irradiating each of the measurement mirror and a reference mirror with a laser beam; and
two beam splitters for splitting a laser beam emitted from the laser light source into at least three laser beams,
the position detector being disposed so as to irradiate the measurement mirror with a first laser beam among three laser beams obtained by the splitting and irradiate different height positions of the reference mirror with a second laser beam and a third laser beam.

9. A charged particle beam apparatus comprising the state apparatus according to claim 8.
